(19) United States
(12) Patent Application Publication
(10) Pub. No.: US 2012/0286271 A1
(43) Pub. Date: Nov. 15, 2012

(54) OXIDE THIN FILM TRANSISTOR RESISTANT TO LIGHT AND BIAS STRESS, AND A METHOD OF MANUFACTURING THE SAME

(76) Inventors: Him Chan OH, Seoul (KR); Sang Hee Park, Daejeon (KR); Chi Sun Hwang, Daejeon (KR); Min Ki Ryu, Seoul (KR)

(21) Appl. No.: 13/467,674

(22) Filed: May 9, 2012

(30) Foreign Application Priority Data
May 13, 2011 (KR) 10-2011-0045099
Sep. 20, 2011 (KR) 10-2011-0094568

(51) Int. Cl. H01L 29/786; H01L 29/04; H01L 21/336; B82Y 40/00; B82Y 99/00

(52) U.S. Cl. 257/57; 438/158; 977/755; 977/890; 257/E29.003; 257/E29.273; 257/E21.411

(57) ABSTRACT

Disclosed are an oxide thin film transistor resistant to light and bias stress, and a method of manufacturing the same. The method includes forming a gate electrode on a substrate; forming a gate insulating layer on an upper part including the gate electrode; forming a source electrode and a drain electrode on the insulating layer; forming an active layer insulated from the gate electrode by the gate insulating layer and formed of an oxide semiconductor and a diffusion barrier film; and forming a protective layer on a portion of the source electrode and drain electrode and the upper part including the active layer, wherein the diffusion barrier film reduces movement of holes and prevents ionized oxygen vacancies from being diffused.

### CROSS-REFERENCE TO RELATED APPLICATIONS

This application is based on and claims priority from Korean Patent Application No. 10-2011-0045099, filed on 05, 13, 2011 and No. 10-2011-0094568, filed on 09, 20, 2011 with the Korean Intellectual Property Office, the disclosure of which is incorporated herein in its entirety by reference.

### TECHNICAL FIELD

The present disclosure relates to an oxide thin film transistor resistant to light and bias stress, and a method of manufacturing the same, and more particularly, to an oxide thin film transistor resistant to light and bias stress, having improved stability when bias stress and light are applied together to the thin film transistor, and a method of manufacturing the same.

### BACKGROUND

A thin film transistor using an oxide semiconductor may use a low temperature process and have high mobility property, and thus, is in the spotlight as a backplane technology of a next-generation display such as an active matrix organic light-emitting diode (AMOLED) display. The thin film transistor using the oxide semiconductor has an energy band gap that is larger than that of visible rays, such that a transparent electronic circuit and display may be implemented, and the thin film transistor may be applied to head-up displays, smart windows, augmented reality technologies, and the like.

In the OLED, liquid crystal display, or transparent display, if the thin film transistor of the backplane is exposed to light during operation, a negative gate bias for maintaining an off-current state is applied over a long period of time, such that the thin film transistor is under light-bias stress.

There is a problem in that the oxide thin film transistor has operation instability of moving a threshold bias in a negative bias direction under the light-bias stress.

A paper of an improvement in light-bias reliability by doping a material such as Hf, Al, and Si in a small amount to a ZnO-based material or forming a multi-element oxide thin film was suggested as a known technology, and there was a report of an improvement in light-bias reliability due to reducing oxygen vacancy defects in the oxide semiconductor through high pressure oxygen heat treatment.

However, the present technologies have problems in that a relatively high process temperature (200° C. or more) is required and, in many cases, mobility of a carrier is reduced. In a case where a plastic substrate having poor heat resistance property is used to implement a flexible display in the spotlight as a next-generation display as an example exhibiting the technical disadvantages, the process temperature cannot be sufficiently increased, there is a problem in that it is difficult to ensure reliability and electrical property.

It is substantially impossible to completely remove defects such as oxygen vacancies in the oxide semiconductor, which are known as a factor of light-bias instability. Accordingly, there is a limit in improving light-bias reliability by a method of reducing oxygen defects through doping or oxygen heat treatment.

As another method, Light-bias reliability may be improved by making the oxide semiconductor layer thin, but there is a problem in that as the thickness of the oxide semiconductor layer is decreased, operation instability is deteriorated under positive bias stress.

### SUMMARY

The present disclosure has been made in an effort to provide a method of easily and simply improving light-bias reliability while an electrical property and positive bias reliability of a thin film transistor are not significantly reduced even though a process temperature is not increased and a special element is not added.

A first exemplary embodiment of the present disclosure provides a thin film transistor, including: a substrate; a gate electrode formed on the substrate; an active layer formed of an oxide semiconductor and a diffusion bather film and insulated from the gate electrode by a gate insulating layer; and a source electrode and a drain electrode connected to the active layer. The diffusion barrier film may reduce movement of holes and prevent ionized oxygen vacancies from being diffused.

The diffusion barrier film may be formed of oxides such as Al₂O₃, HfO₂, ZrO₂, TiO₂, SiO₂, Ga₂O₃, Gd₂O₃, V₂O₃, Cr₂O₃, MnO, Li₂O, MgO, CaO, Y₂O₃, or Ta₂O₅, or nitrides such as SiON, SiNx, and HfNx.

The diffusion barrier film may be formed of oxynitride obtained by mixing two or more elements of oxides and nitrides, and may be formed by laying different kinds of oxides in layers.

The diffusion barrier film may be patterned in a discontinuous form or an arbitrary form to be inserted into an oxide semiconductor.

The diffusion barrier film may be formed in a thickness in the range of 5 to 100 Å.

A second exemplary embodiment of the present disclosure provides a method of manufacturing a thin film transistor, including: forming a gate electrode on a substrate; forming a gate insulating layer on an upper part including the gate electrode; forming a source electrode and a drain electrode on the insulating layer; forming an active layer on an upper part including a portion of the source electrode and drain electrode, wherein an active layer insulates from the gate electrode by the gate insulating layer and is formed of an oxide semiconductor and a diffusion barrier film; and forming a protective layer on the upper part including a portion of the source electrode and drain electrode and the active layer. The diffusion barrier film may reduce movement of holes and prevent ionized oxygen vacancies from being diffused.

The diffusion barrier film may be formed in a thickness in the range of 5 to 100 Å.

According to the exemplary embodiments of the present disclosure, even in a case where a process temperature cannot be largely increased, such as the case of glass or flexible substrate (for example, plastic substrate), light-bias reliability can be improved by forming a diffusion barrier film at the low temperature of 50 to 200° C. to prevent holes and ionized oxygen vacancies from moving .

According to the exemplary embodiments of the present disclosure, a change in electrical property, such as a change in threshold bias, is minimized by adjusting the thickness or insertion position of the diffusion barrier film in the thin film transistor.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating a thin film transistor having a bottom gate and bottom-contact structure according to an exemplary embodiment of the present disclosure.

FIG. 2 is a cross-sectional view illustrating a thin film transistor where a Zinc oxide semiconductor thin film is formed, an Al₂O₃ diffusion barrier film is formed, and a Zinc oxide semiconductor is then deposited thereon.

FIG. 3 is a view illustrating the diffusion barrier film formed in a discontinuous form in the oxide semiconductor according to the exemplary embodiment of the present disclosure.

FIGS. 4 to 6 are views illustrating the diffusion barrier film formed of oxynitride obtained by mixing two or more elements of inorganic oxides and nitrides according to the exemplary embodiment of the present disclosure.

FIG. 7A is a view illustrating a transfer property of a thin film transistor using a Zinc oxide semiconductor thin film having a thickness of 20 nm, into which a diffusion barrier film is not inserted.

FIG. 7B is a view illustrating a change in transfer property over time when a negative gate bias is applied to and light is radiated on the thin film transistor using a Zinc oxide semiconductor thin film having a thickness of 20 nm, into which the diffusion barrier film is not inserted.

FIG. 8A is a view illustrating a transfer property of a thin film transistor where a Zinc oxide semiconductor thin film having a thickness of 5 nm is formed, an Al₂O₃ diffusion barrier film is formed in a thickness of 1.8 nm, and a Zinc oxide semiconductor is then deposited in a thickness of 15 nm thereon.

FIG. 8B is a view illustrating a change in transfer property over time when a negative gate bias is applied to and light is radiated on the thin film transistor where the

Zinc oxide semiconductor thin film having the thickness of 5 nm is formed, the Al₂O₃ diffusion barrier film is formed in a thickness of 1.8 nm, and the Zinc oxide semiconductor is then deposited in a thickness of 15 nm thereon.

FIG. 9A is a view illustrating a transfer property of a thin film transistor where an Al₂O₃ diffusion barrier film is deposited after ZnO is formed in a thickness of 15 nm and ZnO is finally deposited in a thickness of 5 nm.

FIG. 9B is a view illustrating a change in transfer property over time when a negative gate bias is applied to and light is radiated on the thin film transistor where the Al₂O₃ diffusion barrier film is deposited after ZnO is formed in a thickness of 15 nm and ZnO is finally deposited in a thickness of 5 nm.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

Hereinafter, exemplary embodiments of the present disclosure will be described in detail with reference to the accompanying drawings. The configuration of the present disclosure and operation effect thereof may be apparently understood through the following detailed description. The same reference numerals refer to the same elements throughout the specification even though shown in the other drawing, prior to the detailed description of the present disclosure, and known constitutions may not be described in detail if they make the gist of the present disclosure unclear.

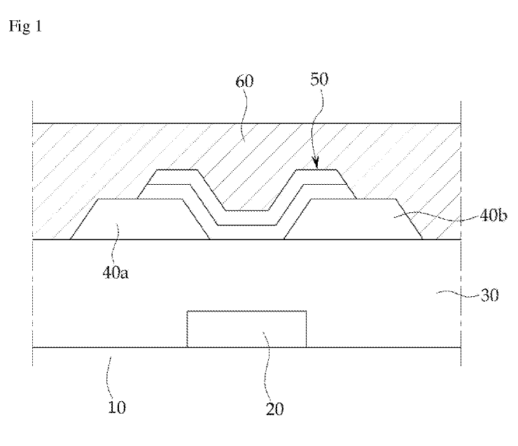

FIG. 1 is a cross-sectional view explaining a thin film transistor according to an exemplary embodiment of the present disclosure, and illustrates an example of the thin film transistor including a bottom gate having a bottom-contact structure.

A gate electrode 20 is formed on a substrate 10.

A gate insulating layer 30 is formed on an upper part including the gate electrode 20, and a source electrode 40a and a drain electrode 40b are formed on the gate insulating layer 30. An active layer 50 and a protective layer 60 are sequentially formed on the upper part including a portion of the source electrode 40a and drain electrode and 40b.

The source electrode 40a and drain electrode and 40b are formed by using an ITO (In-doped tin oxide) material. The Al₂O₃ gate insulating layer 30 is deposited by an atomic layer deposition method, and ZnO semiconductor is used as an active layer.

Finally, an Al₂O₃ thin film is deposited as a protective film layer 60 protecting the active layer 50 from the air in the outside.

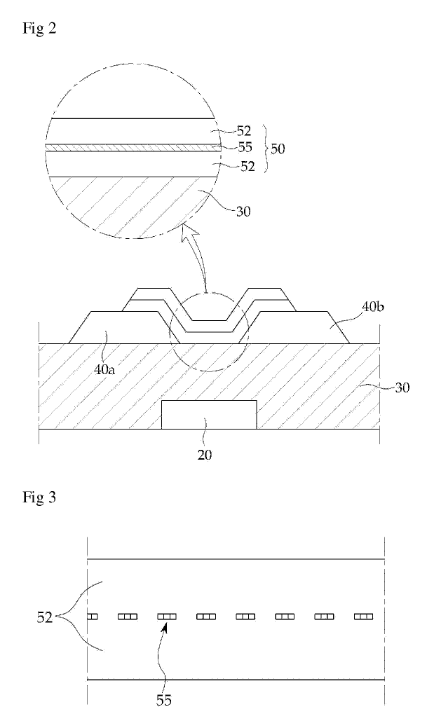

Examining the structure of the active layer 50 referring to FIG. 2, the active layer 50 includes an oxide semiconductor 52 and a diffusion barrier film 55.

Herein, the oxide semiconductor 52 may be formed of a thin film of a material having electrically semiconducting property. For example, the oxide semiconductor may be formed of zinc oxide (ZnO), indium-gallium-zinc oxide (In—Ga—Zn—O), or zinc-tin oxide (Zn—Sn—O), or oxides including at least two or more elements of zinc, indium, gallium, tin and aluminum. Alternatively, the oxide semiconductor may be formed by doping various elements, for example, elements such as Hf and Zr, or adding the elements in a compound form to the aforementioned oxides.

A diffusion barrier film 55 inserted into an oxide semiconductor 52 prevents holes and ionized oxygen vacancies from moving to an interface of semiconductor/insulating film. To be more specific, when negative gate bias and light are applied together, in a case where the thin film transistor including the oxide semiconductors 52 integrated therein is operated, holes and ionized oxygen vacancies having a positive charge in the oxide semiconductor 52 move to the interface formed by the oxide semiconductor 52 and the gate insulating film 30 by the negative gate bias, such that the holes and the ionized oxygen vacancies moving to the interface block the gate bias to move a threshold bias of the thin film transistor in a negative bias direction. A positive charge diffusion barrier film 55 is formed in the active layer 50 in order to prevent movement to the interface of the holes and the ionized oxygen vacancies.

The diffusion barrier film 55 preventing movement of the holes and the ionized oxygen vacancies may be made of a material having a wide band gap so as to reduce movement of the holes.

The diffusion barrier film 55 may use oxides or nitrides having a property for preventing the ionized oxygen vacancies from being diffused. In a case where inorganic oxide is used in the diffusion barrier film, it is better if the bonding strength with oxygen becomes stronger than that of the oxide semiconductor.

Examples of the material having a wide band gap to reduce movement of the holes and a property for preventing oxygen vacancies from being diffused may include oxides such as Al₂O₃, HfO₂, ZrO₂, TiO₂, SiO₂, Ga₂O₃, Gd₂O₃, V₂O₃, Cr₂O₃, MnO, Li₂O, MgO, CaO, Y₂O₃, and Ta₂O₅, or nitrides such as SiON, SiNx, and HfNx.

As illustrated in FIG. 3, formation of the diffusion barrier film 55 is not limited to a continuous thin film form on a plane, and, for example, the diffusion barrier film 55 may be inserted in a discontinuous form such as nano islands, nano dots, and nano particles into the oxide semiconductor, and if necessary may be patterned in an arbitrary form.

A plurality of diffusion barrier films 55 may be inserted into the oxide semiconductor, and a thickness thereof may be adjusted to be in the range of 5 to 100 Å.

Organic and inorganic materials may be simultaneously used as the diffusion barrier film 55, and a thin film form and island, dot, and particle forms may be simultaneously applied.

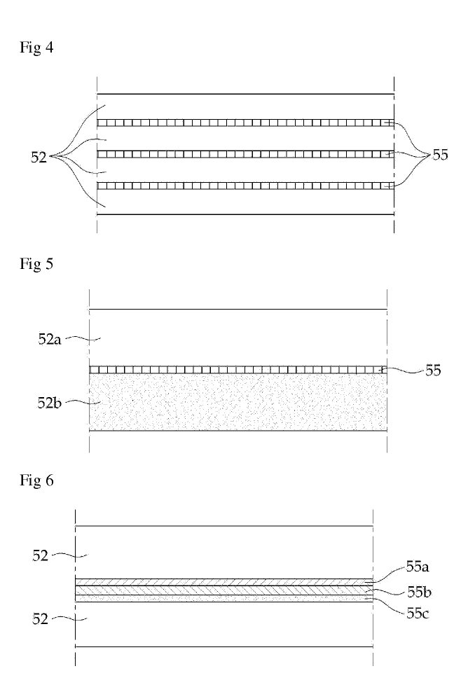

As illustrated in FIGS. 4 to 6, the diffusion barrier film 55 may be formed of oxynitride obtained by mixing two or more elements, and the bather film may be formed by laying different kinds of oxides in layers. For example, the oxides may be laid in a lamination form of Al₂O₃/HfO₂/Al₂O₃, and a film including two elements mixed with each other, such as Al-added TiO₂ may be formed. Different kinds of oxide semiconductor layers may be simultaneously used.

The oxide semiconductor 52 and the diffusion barrier film 55 may use all deposition methods typically used to form the oxide thin film, such as a sputtering method, a chemical vapor deposition method, an atomic layer deposition method, a pulsed-laser deposition method, a spin coating method using a sol-gel solution, and a print method using precursor ink. These methods may also be used together or modified.

In a case where the diffusion barrier film is formed of an organic material, a deposition method that can be introduced in a general organic material thin film forming process, such as a spin coating method, a vacuum thermal evaporation method, and a Langmuir-Blodgett (LB) method may be used.

The structure of the thin film transistor is not limited to a specific form, and may be formed to have various forms. For example, forms such as a coplanar top-gate, a coplanar bottom-gate, a staggered top-gate, and a staggered bottom-gate are feasible, and the present disclosure is implemented without regard to various kinds of modified structures.

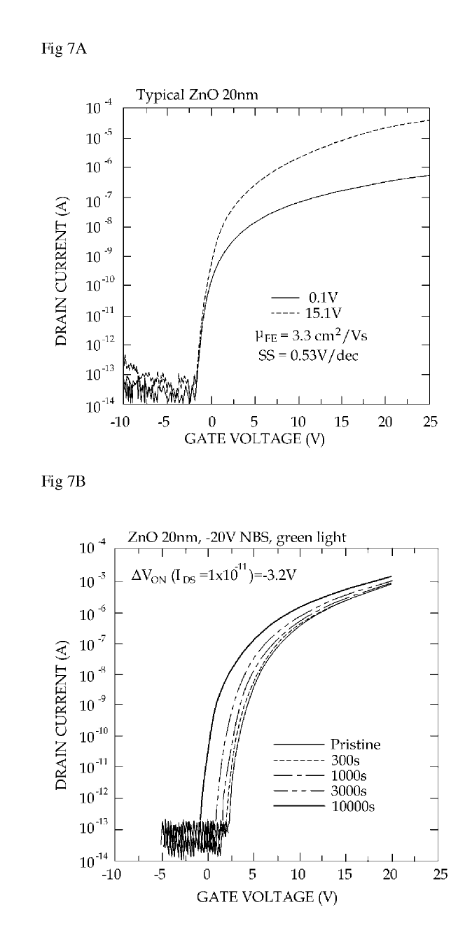

FIG. 7A is a view illustrating a transfer property of a thin film transistor using a Zinc oxide semiconductor thin film having a thickness of 20 nm, into which a diffusion barrier film is not inserted, and FIG. 7B is a view illustrating a change in transfer property over time when a negative gate bias is applied to and light is radiated on the thin film transistor using a Zinc oxide semiconductor thin film having a thickness of 20 nm, into which the diffusion barrier film is not inserted.

As seen from the graphs of FIGS. 7A and 7B, mobility was 3.3 cm²/Vs, and V_{ON} (gate bias when the drain bias was 10 V and the drain current was 10⁻¹¹ A) moved under light-biasbias stress of 10000 sec by −3.2 V.

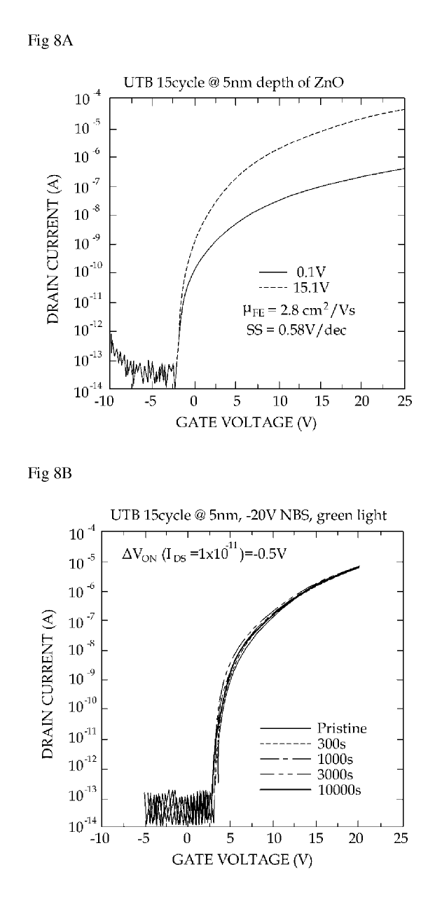

FIG. 8A, similarly to a matter shown in FIG. 2, is a view illustrating a transfer property of a thin film transistor where a Zinc oxide semiconductor thin film having a thickness of 5 nm is formed, a Al₂O₃ diffusion barrier film is formed in a thickness of 1.8 nm, and a Zinc oxide semiconductor is then deposited in a thickness of 15 nm thereon, and FIG. 8B, similarly to a matter shown in FIG. 2, is a view illustrating a change in transfer property over time when a negative gate bias is applied to and light is radiated on the thin film transistor where the Zinc oxide semiconductor thin film having the thickness of 5 nm is formed, the Al₂O₃ diffusion barrier film is formed in a thickness of 1.8 nm, and the Zinc oxide semiconductor is then deposited in a thickness of 15 nm thereon.

As seen from the graphs of FIGS. 8A and 8B, mobility was 2.8 cm²/Vs, and V_{ON} (gate bias when the drain bias was 10 V and the drain current was 10⁻¹¹ A) moved under light-biasbias stress of 10000 sec by −0.5 V. It can be seen that mobility was slightly decreased but movement of V_{ON} was significantly decreased under light-biasbias stress.

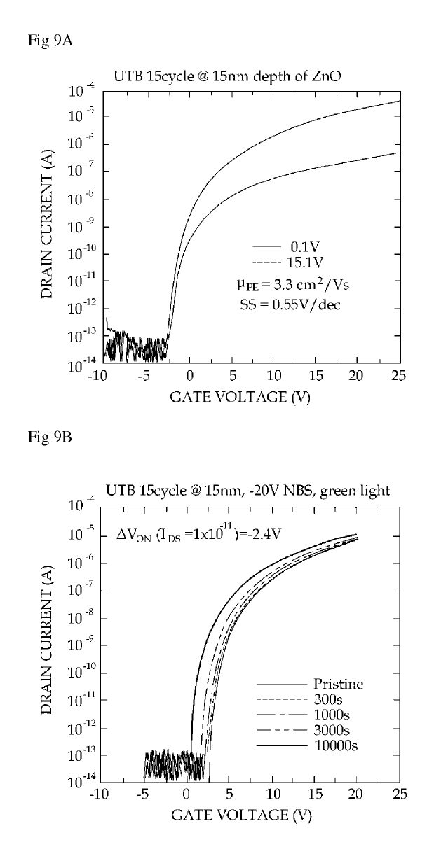

FIG. 9 illustrates a result of deposition of the Al₂O₃ diffusion barrier film after ZnO is formed in a thickness of 15 nm and final deposition of ZnO in a thickness of 5 nm in order not to decrease mobility. Mobility was 3.3 cm²/Vs and not decreased, and mobility of V_{ON} due to light-bias reliability was decreased to −2.4 V.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A thin film transistor, comprising:
a substrate;
a gate electrode formed on the substrate;
an active layer insulated from the gate electrode by a gate insulating layer and formed of an oxide semiconductor and a diffusion barrier film; and
a source electrode and a drain electrode connected to the active layer,
wherein the diffusion barrier film reduces movement of holes and prevents ionized oxygen vacancies from being diffused.

2. The thin film transistor of claim 1, wherein the diffusion barrier film is formed of oxides such as Al₂O₃, HfO₂, ZrO₂, TiO₂, SiO₂, Ga₂O₃, Gd₂O₃, V₂O₃, Cr₂O₃, MnO, Li₂O, MgO, CaO, Y₂O₃, and Ta₂O₅, or nitrides such as SiON, SiNx, and HfNx.

3. The thin film transistor of claim 2, wherein the diffusion barrier film is formed of oxynitride obtained by mixing two or more elements of oxides and nitrides, or is formed by laying different kinds of oxides in layers.

4. The thin film transistor of claim 2, wherein the diffusion barrier film is patterned in a discontinuous form or an arbitrary form to be inserted into an oxide semiconductor.

5. The thin film transistor of claim 2, wherein the diffusion barrier film is formed in a thickness in the range of 5 to 100 Å.

6. A method of manufacturing a thin film transistor, comprising:
forming a gate electrode on a substrate;
forming a gate insulating layer on an upper part including the gate electrode;
forming a source electrode and a drain electrode on the insulating layer;
forming an active layer on an upper part including a portion of the source electrode and drain electrode, wherein an active layer insulates from the gate electrode by the gate insulating layer and is formed of an oxide semiconductor and a diffusion barrier film; and
forming a protective layer on the upper part including a portion of the source electrode and drain electrode and the active layer, wherein the diffusion barrier film reduces movement of holes and prevents ionized oxygen vacancies from being diffused.

7. The method of manufacturing a thin film transistor of claim 6, wherein the diffusion barrier film is formed in a thickness in the range of 5 to 100 Å.
